(19) United States
(12) Patent Application Publication
(10) Pub. No.: US 2009/0206894 A1
(43) Pub. Date: Aug. 20, 2009

(54) Phase-Locked Loop with Adaptive Performance

(75) Inventors: Stanley Bo-Ting Wang, Cupertino, CA (US); Meng-Chang Doong, Sunnyvale, CA (US)

Correspondence Address: THE MUELLER LAW OFFICE, P.C., 12951 Harwick Lane, San Diego, CA, 92130, US

(73) Assignee: ZEROG WIRELESS, INC., Sunnyvale, CA (US)

(21) Appl. No.: 12/032,689

(22) Filed: Feb. 17, 2008

(51) Int. Cl. H03L 7/085; H03L 7/099

(52) U.S. Cl. 327/157

(57) ABSTRACT

A phase-locked loop capable of being dynamically configured to optimize phase-noise performance during different modes of operation. The phase-locked loop may include a switchable charge pump, loop filter and voltage-controlled oscillator having auxiliary circuit components that may be switched in and out to achieve calibration settings for optimizing phase-noise performance for different modes of operation, while minimizing unnecessary power consumption, and without disturbing the stability of the phase-locked loop.

### FIELD OF THE INVENTION

The invention relates generally to phase-locked loops (PLLs), and more specifically to PLLs with adaptive performance characteristics.

### BACKGROUND OF THE INVENTION

PLLs are utilized in a wide range of applications, including frequency synthesizers for wireless and fixed-line communications systems and other information-processing systems. In wireless communications systems, for example, PLL type frequency synthesizers are used to generate periodic waveforms at radio frequency to enable signal down-conversion in a receiver and up-conversion in a transmitter. In such applications, a transmitter and a receiver may share the same frequency synthesizer. A transmitter and receiver that share the same frequency synthesizer may nonetheless have different performance requirements. The performance specifications of a shared frequency synthesizer must be set to meet the more rigid of the two performance requirements. As a result, the frequency synthesizer must be over-designed for the transmission phase or the reception phase. This over-design leads to greater power consumption, which is particularly problematic for mobile communications terminals.

A number of attempts have been made in the prior art to optimize the performance of electronic components, such as frequency synthesizers, that incorporate PLLs. Nevertheless there remains a need for methods and systems that are capable of dynamically optimizing performance of such components during different modes of operation.

### SUMMARY OF THE INVENTION

In one aspect of the invention, a method is provided for optimizing the performance of a phase-locked loop that operates in a first and second mode of operation. The method comprises the steps of (a) altering characteristics of alterable circuit components of the phase-locked loop to achieve a first calibration setting for optimizing the performance of the phase-locked-loop for the first mode of operation; and (2) altering the characteristics of the alterable circuit components of the phase-locked loop to achieve a second calibration setting for optimizing the performance of the phase-locked loop for the second mode of operation.

In another aspect of the invention, a transceiver is provided for use in a first and second mode of operation. The transceiver includes a frequency synthesizer that includes a phase-locked loop. A means is included for altering characteristics of alterable circuit components in the phase-locked loop to achieve a first calibration setting for optimizing performance of the phase-locked loop for the first mode of operation. A means is also included for altering the characteristics of the alterable circuit components in the phase-locked loop to achieve a second calibration setting for optimizing performance of the phase-locked loop for the second mode of operation.

In another aspect of the invention, a communications terminal is provided. The communications terminal includes a transceiver that has a frequency synthesizer that includes a phase-locked loop with a plurality of switchable circuit components that include auxiliary circuit elements. A plurality of switches are included, which are configured to switch the auxiliary circuit elements in and out of the switchable circuit components. A calibration circuit is included for operating the switches prior to a transmit mode to achieve a first calibration setting for optimizing phase-noise performance of the phase-locked loop for the transmit mode. The calibration circuit operates the switches prior to a receive mode to achieve a second calibration setting for optimizing phase-noise performance of the phase-locked loop for the receive mode.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 illustrates a prior art frequency synthesizer that utilizes a phase-locked loop.

FIG. 2 illustrate a typical phase-noise profile for the frequency synthesizer of FIG. 1.

FIG. 3 illustrates a prior art charge pump, loop filter and voltage-controlled oscillator.

FIG. 4 illustrates exemplary embodiments of a charge pump and loop filter that are consistent with the present invention.

FIG. 5 illustrates additional exemplary embodiments of a charge pump and loop filter that are consistent with the present invention.

FIG. 6 illustrates an exemplary embodiment of a voltage-controlled oscillator that is consistent with the present invention.

FIG. 7 illustrates an additional embodiment of a voltage-controlled oscillator that is consistent with the present invention.

FIG. 8 illustrates an exemplary embodiment of a dynamically alterable frequency synthesizer that is consistent with the present invention.

FIG. 9 is a flow chart that illustrates steps associated with an exemplary embodiment of a method of dynamically calibrating a frequency synthesizer in a manner consistent with the present invention.

### DETAILED DESCRIPTION

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

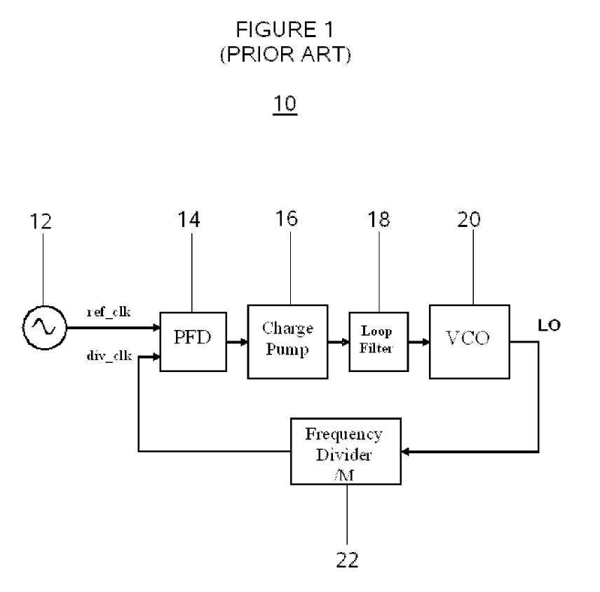

FIG. 1 illustrates a conventional PLL type frequency synthesizer 10. The frequency synthesizer 10 includes a stable, low frequency reference clock source 12, a phase-frequency detector (PFD) 14, a charge pump 16, a loop filter 18, a voltage-controlled oscillator (VCO) 20 and a frequency divider 22. The elements of the frequency synthesizer 10 are configured to form a PLL. The PLL acts as a control loop that generates a high frequency local oscillator (LO) signal from a stable, low frequency reference-clock signal (ref_clk). During operation of the frequency synthesizer 10, the frequency of the LO signal is divided by the frequency divider 22 by a factor of M to generate a divided clock signal (div_clk). The ref_clk and div_clk signals are compared by the PFD 14. A phase difference between the ref_clk and div_clk signals produces a non-zero duration digital pulse from the PFD 14, which in turn produces an analog current or voltage pulse from the charge pump 16. This current or voltage is filtered by the loop filter 18 and is input as a tuning voltage to the VCO 20. When the PLL is first closed, it goes through a settling phase. Once the PLL is settled, the div_clk and ref_clk signals are phase-locked, and the frequency of the LO signal is M times that of the ref_clk and div_clk signals.

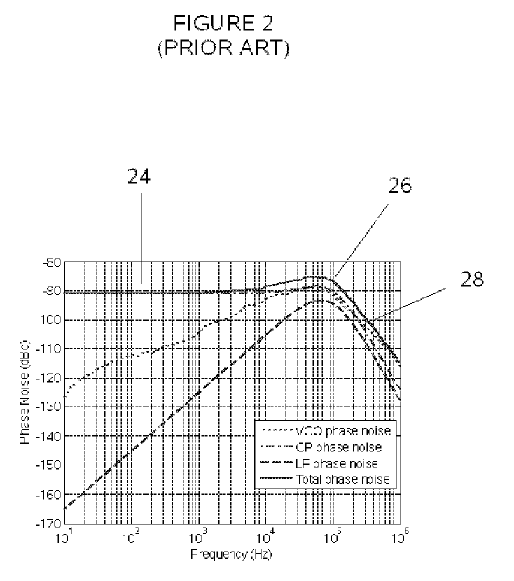

FIG. 2 illustrates the phase noise of a typical Type-II, 3rd-order PLL. The phase noise is the frequency domain representation of random fluctuations in the phase of the output of the PLL. An ideal PLL without phase noise would generate a pure sine wave. In the frequency domain, this would be seen as a single vertical line at the relevant frequency. However, real-world PLLs are affected by phase noise. This phase noise spreads the power of the PLL's signal to adjacent frequencies, resulting in sidebands like the one illustrated in FIG. 2.

FIG. 2 illustrates the phase-noise of a PLL in units of dBc/Hz on the vertical and horizontal axis, respectively. The horizontal axis illustrates various frequency offsets from the PLL's carrier signal frequency. The total phase noise includes a relatively flat passband section 24, a cutoff frequency 26 and a sloping stopband section 28. The phase noise of a PLL may be contributed by various components of a PLL, including its VCO, charge pump and/or loop filter. In FIG. 2, the phase noise of the VCO is labeled “VCO phase noise”. The phase noise for the charge pump is labeled “CP phase noise”. The phase noise from the loop filter is labeled “LF phase noise”. The total phase noise for the PLL is labeled “Total phase noise”.

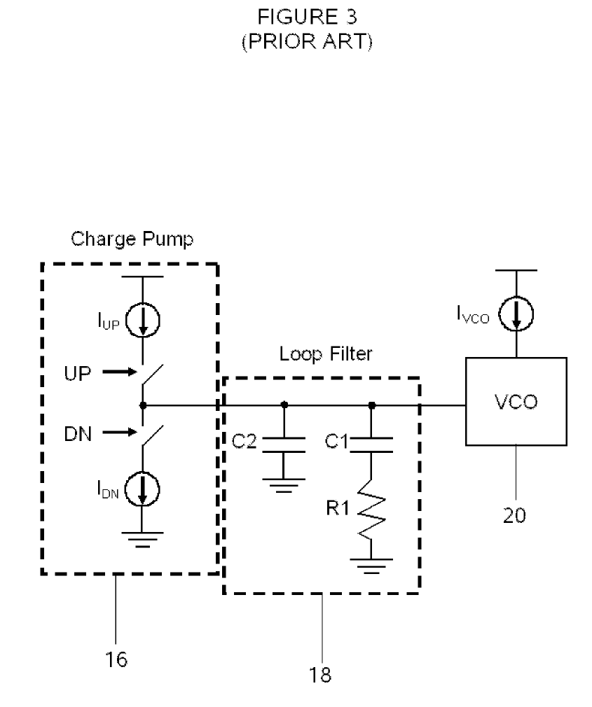

FIG. 3 is a detailed illustration of the prior art charge pump 16, loop filter 18 and VCO 20 of FIG. 1. The charge pump 16 includes a first and second current source, I_{UP} and I_{DN}. These current sources are switched on and off by switches UP and DN to compensate for the phase difference in incoming ref_clk and div_clk signals. The loop filter 18 includes among other things capacitors and resistors, such as C1, C2 and R1, for tuning the frequency characteristics of the loop filter 18. The VCO 20 may be biased by a bias current source I_{VCO}, such as the one illustrated.

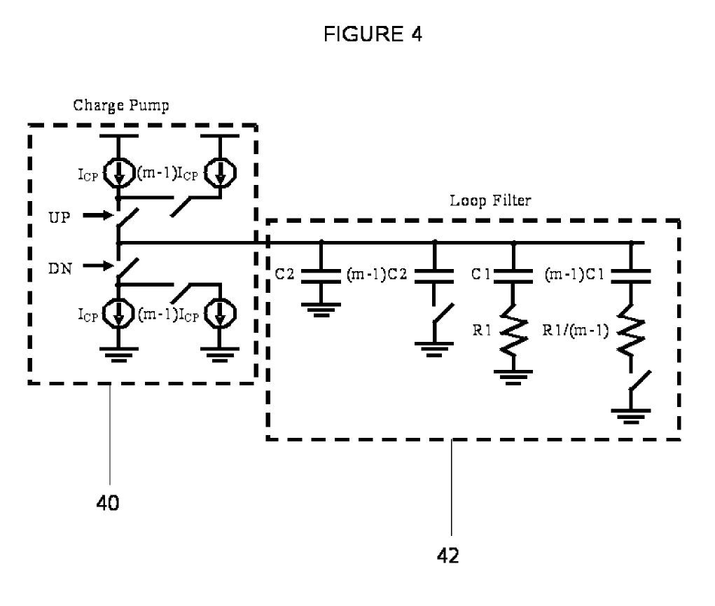

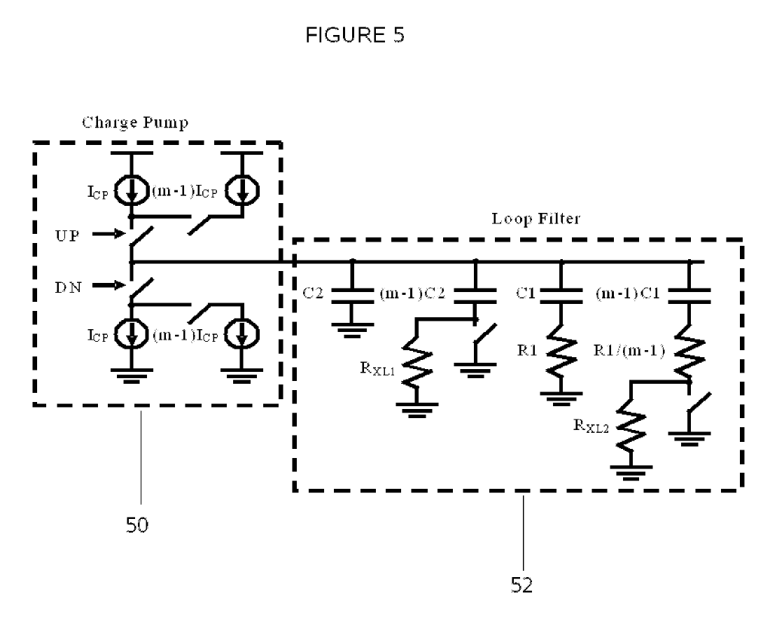

FIG. 4 illustrates exemplary embodiments of an alterable charge pump 40 and an alterable loop filter 42 that are consistent with the present invention. The alterable charge pump 40 and alterable loop filter 42 may include one or more switches for switching in and out auxiliary circuit elements to vary the performance of the corresponding PLL. The auxiliary circuit elements may include, for example, an auxiliary current source (m-1)I_{CP} in the up and down sections of the charge pump 40. The auxiliary circuit elements may also include auxiliary capacitors (m-1)C1 and (m-1)C2 and an auxiliary resistor R1/(m-1) in the loop filter 42. Although switchable components are shown in FIG. 4, the charge pump and loop filter may be altered either discretely or continuously in various manners consistent with the invention. To achieve optimal performance in different modes of operation that have different performance requirements, such as transmission and reception, the characteristics of the switchable charge pump 40 and switchable loop filter 42 may be switched to match each mode of operation. In order to vary the phase noise of the PLL with minimal disturbance to the PLL loop, the switchable circuit elements may be selected such that the bandwidth and phase margin of the loop remain relatively un-changed, while the phase noise increases or decreases. This may be achieved for the embodiments illustrated in FIGS. 4 and 5, for example, by increasing the charge-pump current sources (I_{UP} and I_{DN}) and the loop-filter capacitance (C1 and C2) by a factor of m, while decreasing the charge-pump resistance (R1) by a factor of m. In this way, the loop dynamics of the PLL stay substantially the same, but the phase noise contributed by the charge pump and loop filter may decrease by approximately 10 log₁₀(m) dB (for a given charge-pump-current mismatch percentage). When a lower phase noise state is needed, an extra (m-1)Icp of charge-pump current may be switched in, which makes the new charge-pump current m times larger than the original. The same principle may be applied to the loop filter capacitance and resistance.

When, as discussed above, extra capacitance is switched into a loop filter, it is generally important that the voltage across the extra capacitor is equal to that of the original loop filter output voltage. Otherwise, there may be a disturbance to the loop of the PLL and a finite switching time is required for the PLL to re-settle and seamless operation is not attainable. In one embodiment of the invention, this challenge may be addressed by ensuring that the frequency synthesizer is configured to start up from the low phase noise state in which all the capacitors are charged to the appropriate voltage before any switching occurs. In another embodiment, to avoid leakage or noise coupling that may disturb the constant voltage across the extra capacitors, large resistors R_{XL1} and R_{XL2} may be inserted in series with the capacitors. This arrangement, which ensures that the DC bias voltage is consistently correct, is illustrated in FIG. 5. R_{XL1} and R_{XL2} should be selected such that they are large enough not to affect the impedance of the loop filter.

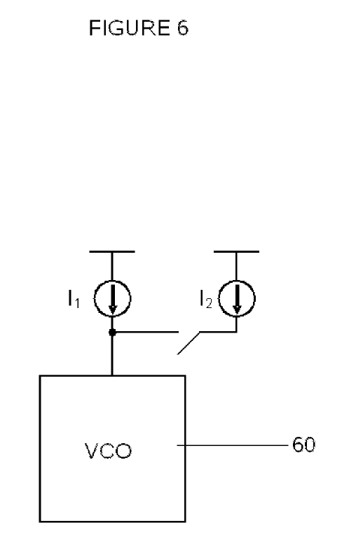

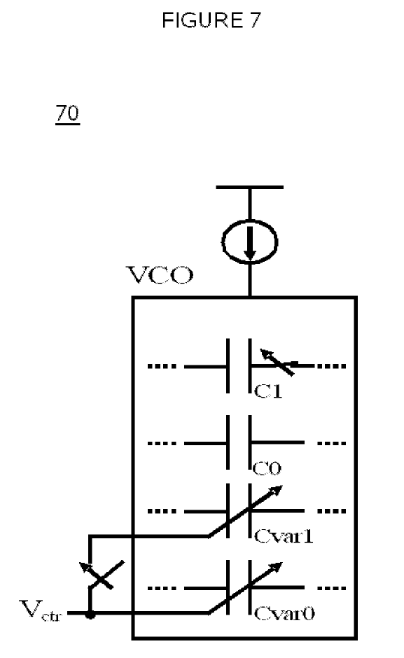

FIGS. 6 and 7 illustrate a first and second embodiment of a VCO 60, 70 that are consistent with the present invention. When the switching time (between transmit and receive mode, or between any high and low noise mode) is less constrained, the following approaches may be utilized to decrease phase noise:

1. Increase the bias current of the VCO 60 by introducing more current into the VCO tank. This may be achieved for example, by switching in a second current source I₂ to supplement the primary current source I₁, as illustrated in FIG. 6. With this approach, the oscillation frequency should not be strongly dependent on the bias current. This will help ensure that any disturbance to the loop will not be severe and that the switching time requirements will be met.

2. Decrease the VCO gain by a factor of m, while increasing the loop-filter resistance by m and decreasing the loop-filter capacitance by m in order to decrease the phase noise contributed by the loop-filter resistor by approximately 10 log₁₀(m). In this case, the loop-filter switching may be accomplished in the manner illustrated in FIGS. 4 and 5, and the gain change of the VCO 70 may be accomplished by switching in or out an extra varactor Cvar1 and switching in or out a linear capacitor C1, as illustrated in FIG. 7. If the voltage across the varactor and linear capacitor that are switched in is not equal to the VCO tank voltage at the moment of switching, the loop will be disturbed and may induce a large switching time before the re-locks of the PLL. A voltage buffer that pre-charges the varactor and/or capacitor may be utilized to mitigate this issue.

3. Decrease the VCO gain by a factor of m and increase the charge-pump current by m to decrease the phase noise contributed by the charge pump by approximately 10 log₁₀(m) and the phase noise contributed by the loop filter by approximately 20 log₁₀(m). This implementation may be achieved in the manner described in heading 2 above.

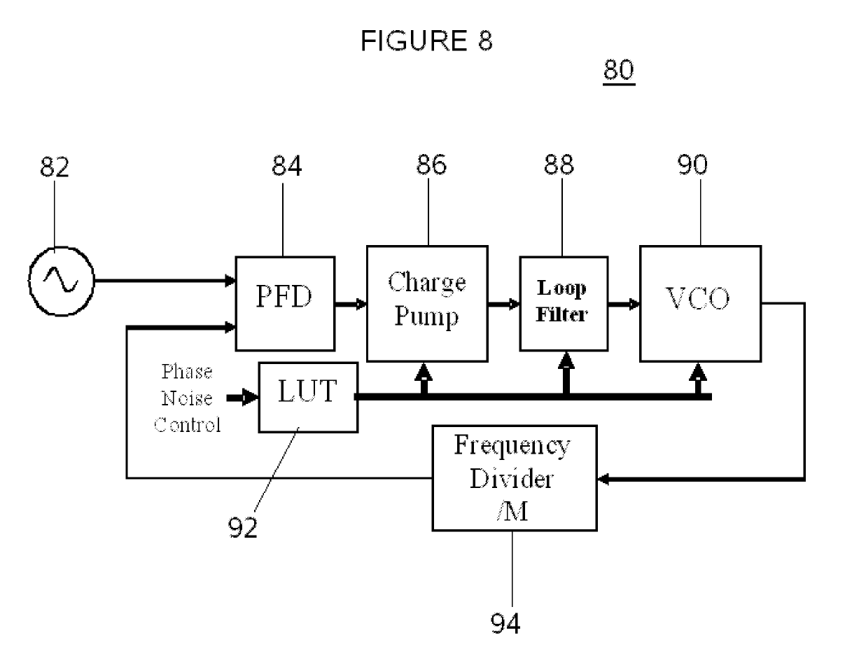

FIG. 8 illustrates an exemplary embodiment of a dynamically configurable frequency synthesizer 80 consistent with the present invention. The frequency synthesizer 80 may include a reference source 82, a PFD 84 and a frequency divider 94. The calibration circuit 90 may also include switchable or otherwise variable circuit components, such as a switchable charge pump 86, a switchable loop filter 88 and/or a switchable VCO 90, for optimizing the performance of the frequency synthesizer for different modes of operation. The frequency synthesizer 80 may include a look-up table (LUT) 102 or other control elements (not illustrated) for altering the characteristics of the switchable circuit components to optimize the phase-noise performance of the frequency synthesizer during different modes of operation.

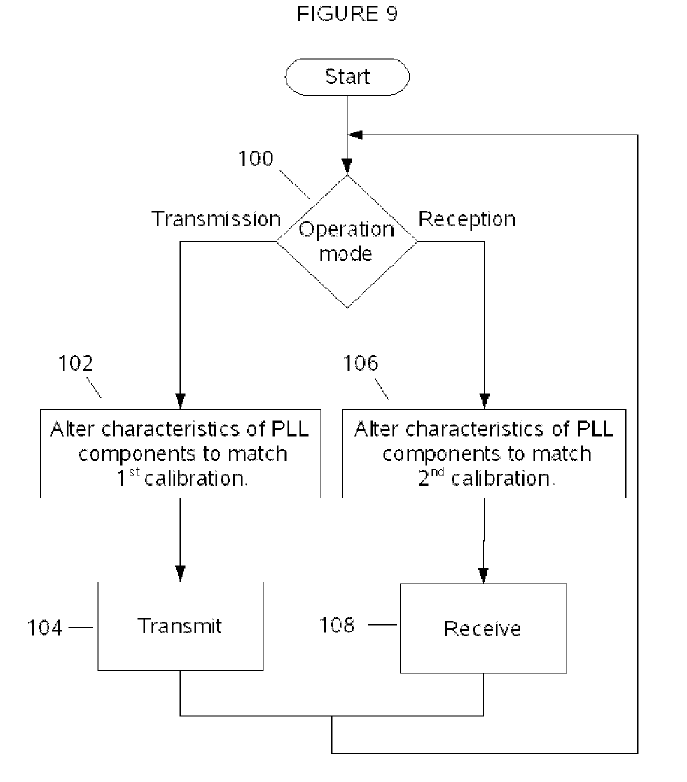

FIG. 9 is a flow chart that illustrates steps associated with an exemplary embodiment of a method of dynamically calibrating a PLL in a manner consistent with the present invention. In the illustrated embodiment, characteristics of one or more switchable or variable circuit components of the PLL are altered to match different modes of operation. The alteration of these characteristics may include, for example, the alteration of capacitance, resistance and/or current or voltage characteristics of the circuit components. The switchable or variable circuit components may include, for example, the charge pump, loop filter and/or VCO of the frequency synthesizer. The alteration of the circuit components leads to two or more calibration settings for the PLL that correspond to different modes of operation. In this way, the phase-noise characteristics or other performance characteristics of the PLL, like power consumption, may be optimized for the different modes of operation. This optimization may involve, for example, shifting the phase noise of the PLL substantially up or down with respect to a dBc axis, without substantially changing the passband or cutoff frequency of the phase noise.

With reference to FIG. 9, an operation mode may be determined in step 100. If the operation mode is, for example, a transmission mode, in step 102 the characteristics of the switchable or variable PLL circuit components may be altered to match a 1^{st} calibration setting for optimizing the phase-noise performance of the PLL for the transmission mode. In step 104, the transmission is then performed. Alternatively, if the operation mode is a reception mode, in step 106 the characteristics of the switchable or variable PLL circuit components may be altered to match a 2^{nd} calibration setting for optimizing the phase-noise performance of the PLL for the reception mode. In step 108, the reception is completed. After completion of an operation mode, the process returns to step 100 to determine the next operation mode.

Although embodiments of the invention have been discussed primarily with respect to specific embodiments thereof, other variations are possible. For example, various components other than frequency synthesizers that utilize PLLs are suitable for use with the present invention. Moreover, although reference is made in embodiments to the optimization of phase noise performance, methods and systems consistent with the present may be utilized to optimize other performance characteristics as well. In addition, steps may be performed by hardware or software, as desired. Steps can also be added to, taken from or modified from the steps in this specification without deviating from the scope of the invention. In general, any flowcharts presented are only intended to indicate one possible sequence of basic operations to achieve a function, and many variations are possible. Those of skill in the art will also appreciate that methods and systems consistent with the present invention are suitable for use in a wide range of applications, such as radio-frequency identification (RFID) systems, cellular communication systems (including but not limited to TDMA, CDMA, GSM, GPRS and WCDMA systems), as well as other wireless and fixed-line communications systems and information-processing systems.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A method of optimizing the performance of a phase-locked loop for use in a first and second mode of operation, the method comprising the steps of:
altering characteristics of alterable circuit components of said phase-locked loop to achieve a first calibration setting for optimizing said performance of said phase-locked loop for said first mode of operation; and
altering said characteristics of said alterable circuit components of said phase-locked loop to achieve a second calibration setting for optimizing said performance of said phase-locked loop for said second mode of operation.

2. The method of claim 1 wherein said performance being optimized comprises the phase-noise performance of said phase-locked loop.

3. The method of claim 1 wherein said step of altering characteristics comprises switching in and out auxiliary circuit elements in said alterable circuit components.

4. The method of claim 2 wherein said step of altering characteristics further comprises altering the dBc level of the phase noise of said phase-locked loop without substantially altering the frequency characteristics of the passband or cutoff frequency of said phase noise.

5. The method of claim 3 wherein said auxiliary circuit elements comprise elements of a charge pump and a loop filter.

6. The method of claim 3 wherein said auxiliary circuit elements comprise elements of a charge pump and a voltage-controlled oscillator.

7. The method of claim 3 wherein said auxiliary circuit elements comprise elements of a loop filter and a voltage-controlled oscillator.

8. The method of claim 3 wherein said auxiliary circuit elements comprise elements of a charge pump, a loop filter and a voltage-controlled oscillator.

9. A transceiver for use in a first and second mode of operation, comprising:
a frequency synthesizer including a phase-locked loop;
means for altering characteristics of alterable circuit components in said phase-locked loop to achieve a first calibration setting for optimizing performance of said phase-locked loop for said first mode of operation; and
means for altering said characteristics of said alterable circuit components in said phase-locked loop to achieve a second calibration setting for optimizing performance of said phase-locked loop for said second mode of operation.

10. The transceiver of claim 9 wherein said performance being optimized comprises the phase noise characteristics of said phase-locked loop.

11. The transceiver of claim 9 wherein said means for altering characteristics includes means for switching in and out auxiliary circuit elements.

12. The transceiver of claim 10 wherein said means for altering parameters further comprises means for altering the dBc level of the phase noise of said phase-locked loop without substantially altering the frequency characteristics of the passband or cutoff frequency of said phase noise.

13. The transceiver of claim 11 wherein said auxiliary circuit elements comprise elements of a charge pump and a loop filter.

14. The transceiver of claim 11 wherein said auxiliary circuit elements comprise elements of a charge pump and a voltage-controlled oscillator.

15. The transceiver of claim 11 wherein said auxiliary circuit elements comprise elements of a loop filter and a voltage-controlled oscillator.

16. The transceiver of claim 11 wherein said auxiliary circuit elements comprise elements of a charge pump, a loop filter and a voltage-controlled oscillator.

17. A communications terminal, comprising:
a transceiver having a frequency synthesizer including a phase-locked loop with a plurality of switchable circuit components including auxiliary circuit elements;
a plurality of switches configured to switch said auxiliary circuit elements in and out of said switchable circuit components; and
a calibration circuit (a) for operating said switches prior to a transmit mode to achieve a first calibration setting for optimizing phase-noise performance of said phase-locked loop for said transmit mode; and (b) for operating said switches prior to a receive mode to achieve a second calibration setting for optimizing phase-noise performance of said phase-locked loop for said receive mode.

18. The communications terminal of claim 17 wherein said first and second calibration settings are selected such that the phase noise of said phase-locked loop is moved with respect to dBc without substantially affecting the frequency position of the passband or cutoff frequency of said phase noise.

19. The communications terminal of claim 17 wherein said switchable circuit components comprise a charge pump and a loop filter.

20. The communications terminal of claim 17 wherein said switchable circuit components comprise a charge pump and a voltage-controlled oscillator.

21. The communications terminal of claim 17 wherein said switchable circuit components comprise a loop filter and a voltage-controlled oscillator.

22. The communications terminal of claim 17 wherein said switchable circuit components comprise a charge pump, a loop filter and a voltage-controlled oscillator.
